(19) United States
(12) Patent Application Publication
(10) Pub. No.: US 2009/0217977 A1
(43) Pub. Date: Sep. 3, 2009

(54) Photonic crystal architectures for frequency- and angle-selective thermal emitters

(76) Inventors: Marian Florescu, Philadelphia, PA (US); Jonathan Dowling, Baton Rouge, LA (US); Hwang Lee, Baton Rouge, LA (US)

Correspondence Address: ADAMS AND REESE LLP, 4400 ONE HOUSTON CENTER, 1221 MCKINNEY, HOUSTON, TX, 77010, US

(21) Appl. No.: 12/378,853

(22) Filed: Feb. 20, 2009

Related U.S. Application Data
(60) Provisional application No. 61/030,610, filed on Feb. 22, 2008.

(51) Int. Cl. H01L 31/00; G02B 6/10

(52) U.S. Cl. 136/256; 385/129

(57) ABSTRACT

A photonic-crystal based frequency- and angle-selective absorber for solar TPV systems is provided. The solar radiation absorber includes at least one photonic crystal with absorptivity over a broad range of frequencies, improved absorptivity within a selected solid angle, and reduced absorptivity outside the selected solid angle.

### CROSS-REFERENCE TO RELATED APPLICATIONS

The present application claims the benefit of prior U.S. Provisional Application No. 61/030,610, filed Feb. 22, 2008, which is hereby incorporated by reference.

### STATEMENT REGARDING FEDERALLY SPONSORED RESEARCH OR DEVELOPMENT

Not applicable.

### THE NAMES OF THE PARTIES TO A JOINT RESEARCH AGREEMENT

Not applicable.

### INCORPORATION-BY-REFERENCE OF MATERIAL SUBMITTED ON COMPACT DISC

Not applicable.

### BACKGROUND OF THE INVENTION

1. Field of the Invention

The present invention relates generally to devices made of a material having a high index of refraction that allows them to confine, guide, and transmit light, and more specifically to a new class of angle- and frequency-selective structures for illuminating photoelectric cells. In particular, the present invention addresses the conversion of thermal energy into electrical energy by means of thermophotovoltaic elements. The invention employs the spectral and angular properties of microstructured photonic crystals to achieve important improvements in the efficiency of thermal and/or solar energy conversion.

2. Description of Related Art

Photonic crystals constitute a new class of dielectric materials in which the basic electromagnetic interaction is controllably altered over certain frequencies and length scales. S. John, Phys. Rev. Lett. 58 (1987) 2486; E. Yablonovitch, Phys. Rev. Lett. 58 (1987) 2059. A photonic band gap (PBG) occurs in a periodic dielectric or metallic media, similarly to the electronic band gap in semiconductor crystals. In the spectral range of the PBG, the electromagnetic radiation light cannot propagate. The ability to tailor the properties of the electromagnetic radiation in a prescribed manner enables the design of systems that accurately control the emission and absorption of light.

In the context of quantum optics, the radiation reservoir associated with a photonic crystal presents a drastic departure from the ordinary vacuum case, and the strong modification of the local density of photonic modes in the PBG give rises to new phenomena including the inhibition and enhancement of the spontaneous emission, strong localization of light, formation of atom-photon bound states, quantum interference effects in spontaneous emission, single atom and collective atomic switching behavior by coherent resonant pumping, and atomic inversion without fluctuations. See, e.g., Phys. Rev. Lett. 58 (1987) 2059; Phys. Rev. Lett. 58 (1987) 2486; Phys. Rev. A 50 1764 (1994); Phys. Rev. Lett. 79 (1997) 205; and Phys. Rev. Lett. 78 (1997) 1888, respectively. These remarkable features have attracted a considerable interest in important technological applications of photonic crystals such as low-threshold micro-lasers, ultra-fast all-optical switches, and micro-transistors. See Science 284 (1999) 1819; Appl. Phys. Lett. 75 (1999) 316; Phys. Rev. A 64 (2001) 033801; J. Opt. A 3 (2001) S103; Phys. Rev. A 69 (2004) 053810. Most of the applications of photonic crystals are exploiting the fundamental nonlinear effects facilitated by the photonic band edge that separates the photonic band gap from the continuum of propagating modes.

In particular, the modifications of the spontaneous emission rate of atoms inside the photonic crystal structure determine, in turn, important alterations of thermal radiative processes. Thermal radiation is just spontaneous emission thermally driven and in thermal equilibrium with its material surroundings. In 1999, Cornelius and Dowling suggested the use of PBG materials for the modification of thermal emission. C. M. Cornelius and J. P. Dowling, Phys. Rev. A 59 (1999) 4736. More recently, the ability of photonic crystals to significantly alter thermal radiation processes has received considerable attention. Thermal emission modification has been experimentally demonstrated in 2000, using a thin slab of 3D photonic crystal on a silicon substrate. S. Y. Lin et al., Phys. Rev. B 62 (2000) R2243. Pralle et al. demonstrated a thermally excited, narrow-band, mid infrared source using a PBG technique. M. U. Pralle et al. Appl. Phys. Lett. 81 (2002) 4685. Recently, researchers at Sandia Labs demonstrated a high-efficiency TPV system using tungsten photonic crystals. See Appl. Phys. Lett. 83 (2003) 380; Appl. Phys. Lett. 83 (2003) 593; Opt. Lett. 28 (2003) 1909.

By optimizing the coupling of the multi-mode radiation field of a PBG material and a spatially extended collection of atomic or electronic emitters, it is possible to achieve dramatic modifications of Planck's blackbody radiation spectrum. See Appl. Phys. Lett. 83 (2003) 380. In the photonic band-gap spectral range the thermal emission of radiation is strongly suppressed. Whereas for specific frequencies in the allowed photonic bands, that correspond to transmission resonances of the photonic crystal, the thermal emission of radiation is resonantly enhanced up to the black-body limit.

In general, photonic crystals are characterized by the dispersion relation or band structure (relationship between the frequency and the wave-vector) and by the optical density of states (the number of electromagnetic modes at a specific frequency and at a location within the photonic crystal) (see, e.g., FIG. 4), which can be employed to infer their radiative response.

### BRIEF SUMMARY OF THE INVENTION

Disclosed is a photonic-crystal based frequency- and angle-selective absorber for solar TPV systems. Such a device absorbs the incoming solar radiation only into a narrow range of incident angle, corresponding to the angle subtended by the Sun. Additionally, the photonic crystal structure presents an enhanced spectral response on a range of frequencies centered on the photocell band-gap frequency. Using the angular selectivity of the absorber, the loss of energy by the radiation of the intermediate absorber into outside of solid angle extended by the Sun can be eliminated. Hence, the conversion efficiency of a solar cell can be enhanced without using concentration of the sun light. Using the frequency selectivity of the photonic crystal based solar absorber, the production of radiation with frequencies around the photocell band-gap frequency is enhanced providing further increase in the efficiency of the solar radiation conversion into electric current.

### BRIEF DESCRIPTION OF THE SEVERAL VIEWS OF THE DRAWINGS

FIG. 1. is a schematic of a TPV energy conversion scheme, showing spectral funneling of thermal radiation by photonic crystals. By designing a photonic band gap in prescribed frequency region of the emission spectrum, the structure becomes unable to radiate at these frequencies and the corresponding energy is re-radiated in the allowed spectral range. As a consequence, the intensity of the blackbody emission at these frequencies increases, and the photonic crystal emitter radiates the same power as it would a blackbody maintained at a higher temperature.

FIG. 2 shows the dependence of the directional spectral emissive power within the 2D model photonic crystal on the emission angle for a number of frequencies. The model system consists of a 2D square lattice of dielectric cylinders with dielectric constant=8.41, radius r/a=0.15 in air (with a, the lattice constant). The frequencies are measured in units of ω₀=2πc/a.

FIG. 3 shows different waveguide architectures that can be employed to achieve angular control of the thermal radiation over a predefined spectral range.

FIG. 4 shows band structure calculations for a 2D photonic crystal waveguide. The line indicated by the arrow denotes electromagnetic modes localized within the waveguide channel for which the emission and absorption of thermal radiation takes place only for narrow angle along the channel direction. The model system consists of a 2D square lattice of dielectric cylinders with dielectric constant=8.41, radius r/a=0.15 in air (with a, the lattice constant) with one line of dielectric rods missing structure as shown on the left panel of FIG. 3.

FIG. 5 shows the design of a PBG wide-band angular selective absorber. The micro-structure consists of a waveguide channel in a 2D photonic crystal, which is embedded in a 3D photonic crystal. The ID waveguide is generated by removing one row of rods in the longitudinal direction. The 3D photonic crystal is assumed to be a woodpile structure that presents a photonic band gap of about 20% of the mid-gap frequency. In this example, the 2D photonic crystal consists of square rods of width a_{2D}/a=0.3. The width and the height of the stacking rods in the woodpile structure are a_{3D}/a=0.25 and h_{3D}/a=0.3, respectively, where a is the dielectric lattice constant of the embedding 3D photonic crystal. See, e.g., M. Florescu, S. Scheel, H. Haeffner, H. Lee, D. V. Strekalov, P. L. Knight, J. P. Dowling, Europhysics Letters 69, 945 (2005); A. Chutinan, S. John and O. Toader, Phys. Rev. Lett., 90 (2003) 123901; M. Florescu and S. John, Phys. Rev. A, 69 (2004) 053810; and Wang R. and John S., Phys. Rev. A, 70 (2004) 043805.

FIG. 6 shows a schematic dispersion relation of the PBG hetero-structure described depicted in FIG. 5 for propagation along the waveguide direction. By removing one row of rods, the linear defect supports a single waveguide mode. By appropriately choosing unit cell size, the mode will experience a sharp cutoff in the spectral region around the photocell band-gap frequency. See, e.g., M. Florescu, H. Lee, I. Puscasu, M. Pralle, D. Z. Ting and J. P. Dowling, Solar Energy Materials and Solar Cells 91 (2007) 1599.

FIG. 7 shows an alternate approach for angular and frequency-selective photonic crystal absorbers. The structure consists of a periodic arrangement of “OmniGuide” fibers. Each fiber consists of an axially uniform, cylindrically symmetric arrangement of dielectric bilayers made out of dielectric materials with indices of refraction {n₁, n₂} and thicknesses {d₁, d₂}. “OmniGuide” fibers have been manufactured using tellurium (refractive index n₁=4.6) and polystyrene (refractive index n₂=1.59). See, e.g., S. Hart, G. Maskaly, B. Temelkuran, P. Prideaux, J. Joannopoulos, and Y. Fink, Science 296, 510 (2002); and B. Temelkuran, S. Hart, G. Benoit, J. Joannopoulos, and Y. Fink, Nature 420, 650 (2002). The thicknesses of the bilayer components can be optimized to provide a large spectral range of single angle propagation. For example, if the thickness of the layers is chosen such that d₁=d₂/2 and the internal core has radius r₁=2.14 a (with the “lattice” constant a=d₁+d₂), the fiber presents ominidirectional functionality for a spectral range Δω/ω₀≈60%, centered on ω₀=0.2×2πc/a. See, e.g., P. Bermel, J. D. Joannopoulos, Y. Fink, A. Lane and C. Tapalian, Phys. Rev. B 69, 035316 (2004); S. Hart, G. Maskaly, B. Temelkuran, P. Prideaux, J. Joannopoulos, and Y. Fink, Science 296, 510 (2002); and B. Temelkuran, S. Hart, G. Benoit, J. Joannopoulos, and Y. Fink, Nature 420, 650 (2002). In order to match the solar spectrum range central frequency, lattice constants a≈100 nm are required.

FIG. 8 is a schematic of the photonic crystal-based TPV energy conversion system. A photonic crystal angle-selective absorber is heated by absorbing thermal radiation. The angle-selective absorber is in thermal contact (both by radiative and non-radiative means) with a second photonic crystal based emitter, which acts a frequency-selective emitter, with a resonance frequency centered around the photocell band-gap frequency. The photovoltaic (PV) cell is illuminated by radiation from emitter and the residual radiation that is not absorber by the photocell is recycled with a mirror.

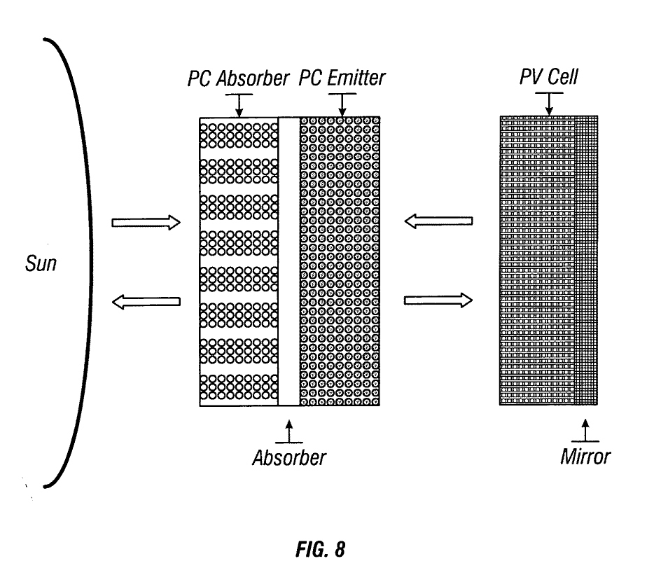

### DETAILED DESCRIPTION OF THE INVENTION

Even though the claims hereinafter may refer to substances, components and/or ingredients in the present tense (“comprises”, “is”, etc.), the reference is to the substance, component or ingredient as it existed at the time just before it was first contacted, blended or mixed with one or more other substances, components and/or ingredients, or if formed in solution, as it would exist if not formed in solution, all in accordance with the present disclosure. It matters not that a substance, component or ingredient may have lost its original identity through a chemical reaction or transformation during the course of such contacting, blending, mixing, or in situ formation, if conducted in accordance with this disclosure.

Each and every patent or publication referred to in any portion of this specification is incorporated in toto into this disclosure by reference, as if fully set forth herein.

Photovoltaic (PV) solar energy conversion systems (or solar cells) are the most widely used power systems. However, these devices suffer of very low conversion efficiency. This is due to the wavelength mismatch between the narrow wavelength band associated with the semiconductor energy gap and the broad band of the (blackbody) emission curve of the Sun. The power loss is associated with both long-wavelength photons that do not have enough energy to excite electron-hole pairs across the energy gap (leading to a 24% loss in silicon, for instance) and short-wavelength photons that excite pairs with energy above the gap, which thereby waste the extra kinetic energy as heat (giving a 32% loss in silicon). Another important cause of low conversion efficiency of generic photovoltaic energy converters is related to the angular mismatch between the angular distribution of the incoming solar radiation and the angular distribution of the radiation emitted by the absorbing materials placed on the Sun-facing parts of solar energy converters. From the Earth surface, the angle subtended by the Sun is extremely small θ_{S}=10⁻⁵ steradians. However, a conventional planar surface emits radiation isotropically in all 2π steradians. Due to this angular mismatch, the planar surface reaches thermal equilibrium at a much lower temperature than the Suns' temperature.

In order to increase the efficiency of solar energy conversion one needs to address these fundamental issues related to the spectral and angular mismatch. Conventionally, the spectral mismatch is addressed by recycling the photons with frequency larger than the solar cell band-gap frequency, through the use of a spectrally dependent coupling between the absorber and the cell, whereas the angular mismatch is avoided by using of solar radiation concentrators, which are additional optical devices that collect the solar radiation on a large area and focus it on the solar cell. However, both approaches have their limitations and can result in additional sources of efficiency degradation. The radiation that does not match the cell band-gap frequency is recycled by simply placing a filter in front of the cell and recycled back to the absorber. Since the only spectrally sensitive element is the filter, the recycling of the photons is a very inefficient process with a high probability that the photons with frequency larger that the cell band-gap escape the conversion system before actually being absorbed by the cell and converted to electrons. On the other hand, a concentrator device mimics a brighter solar source at the expense of the collection area, which is not desirable in most applications where the size and/or the mass are a critical concern.

The present invention is based on using microstructured photonic systems (such as photonic crystals) to increase the efficiency of the solar energy converters, and exploits three fundamental characteristics of these systems:

1. Photonic-Crystal Based Frequency-Selective Absorber/Emitter

The solar radiation absorber is a key component of a solar energy conversion system, and its optical properties influence dramatically the conversion efficiency of the system. The solar energy absorber needs to be spectrally selective, characterized by a high absorptance of the solar energy, particularly in the visible and near-infrared regions (most of the solar radiation is concentrated into a spectral range encompassing the visible and infrared regions: approximately 85% of the total photon flux from the sun is between 300 nm and 1,400 nm), as well as by a low emissivity in the long wavelength (infrared) region.

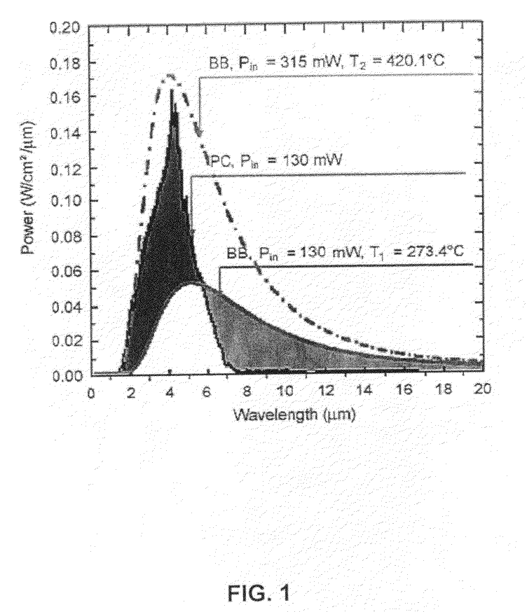

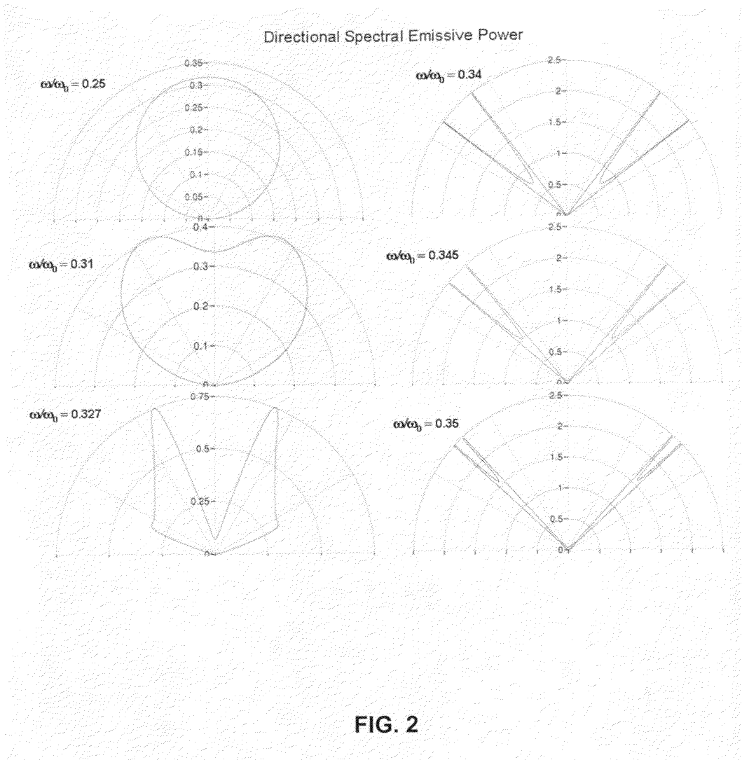

One of advantages of using a photonic crystal as a frequency-selective absorber is that the spectral selection can be made inherent, without additional filters. The ability of photonic crystals to provide selective emission of radiation that is matched to the peak spectral response of a photovoltaic cell has been exploited before by Lin et al. to propose new thermophotovoltaic devices with increased efficiency. See, e.g., “Thermophotovoltaic energy conversion using photonic bandgap selective emitters”, U.S. Pat. No. 6,583,350. We are going beyond that and employ the ability of photonic crystals to funnel the broadband thermal radiation into a prescribed spectral range centered on the photovoltaic cell band-gap frequency rather than just increase the probability of emission on a specific frequency range as in Lin's invention. This principle is illustrated in FIG. 2, which shows a comparison between the intensity emitted by a photonic crystal sample when electrically heated, which reaches a temperature of 420° C. when is electrically heated with an input power of 135 mW (black curve), and two blackbody systems, one kept at the same temperature as the photonic crystal at the expense of using a higher input power (315 mW) and a second one exposed at the same input power as the photonic crystal sample, but having a lower temperature of 273.4° C. See M. Florescu, H. Lee, I. Puscasu, M. Pralle, D. Z. Ting and J. P. Dowling, Solar Energy Materials and Solar Cells 91 (2007) 1599. Clearly, the emission of radiation in with shorter wavelengths is enhanced concomitantly with a dramatic reduction of the emission at longer wavelengths. Moreover, by eliminating the emission in certain frequency bands (corresponding to the spectral range of the PBG), the emission is enhanced in the spectral region corresponding to the allowed bands and, at the same input power, the photonic crystal reaches a higher temperature than the corresponding blackbody. This is solely due to the funneling of the thermal radiation from the forbidden spectral range (the lighter shaded area on the right side of FIG. 1) into the allowed spectral range (the darker shaded area on the left side of FIG. 1). Therefore, the heated photonic crystal emitter achieves thermal equilibrium at a higher temperature than would otherwise be possible. These facts demonstrate the possibility of leveraging the funneling properties of photonic crystals to improve the spectral coupling of an emitter into the acceptance band of a PV cell.

2. Angular-Selective Absorber

In addition to the frequency selectivity, thermal emission of the photonic crystal has the angular selectivity that can be employed to increase the efficiency of the solar energy conversion system. If the radiation emitted and absorbed by a photonic crystal is limited to a narrow angular range around a certain direction, it becomes possible to reduce the losses due to the reemission of the thermal radiation in all available directions by a planar surface. The optimum situation occurs when the solid angle of the emission is the same as the solid angle extended by the Sun. In this case, due to the decrease of the radiation loss, the angular-sensitive photonic crystal sample will achieve a higher thermal equilibrium temperature than a regular flat surface. A larger value of temperature difference between the absorber and the PV cell becomes available, leading to higher conversion efficiencies.

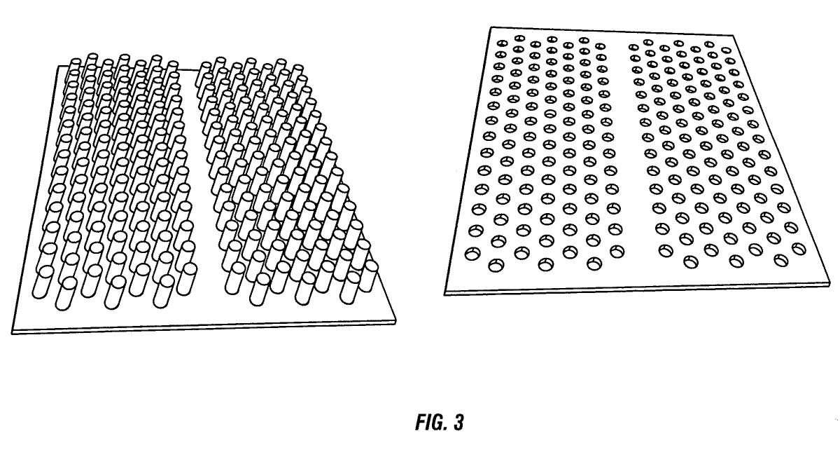

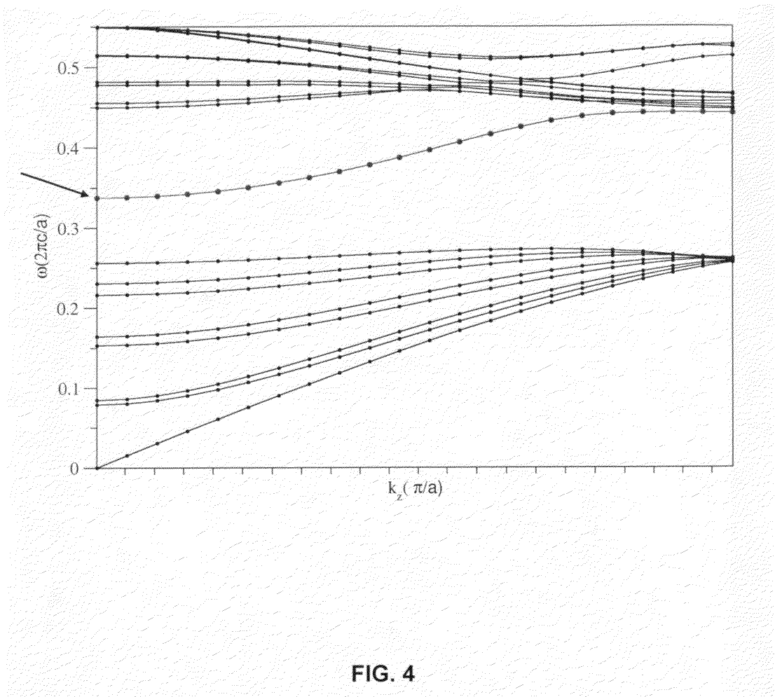

We have shown before that two-dimensional photonic crystals present thermal antenna functionality. See, e.g., M. Florescu, K. Busch and J. P. Dowling, Phys. Rev. B 75, 201101 (R) (2007). FIG. 3 shows a polar plot of the directional spectral emissive power for the thermal radiation emitted by a two-dimensional photonic crystal sample (top right panel inset). As depicted in FIG. 4, for specific frequencies, there exists a narrow range of large absorption around a certain angle of incidence, while for all other angles, absorption/emission becomes negligible.

3. Wide-Band Angular-Selective Absorber

The thermal antenna functionality, in which enhanced angular response is available only for specific frequencies, is a precursor of wide-band angular selectivity of more complex photonic crystal architectures. Indeed, here we show that further engineering of photonic crystal architectures enables full directional control of the radiation absorption/emission over a broad range of frequencies.

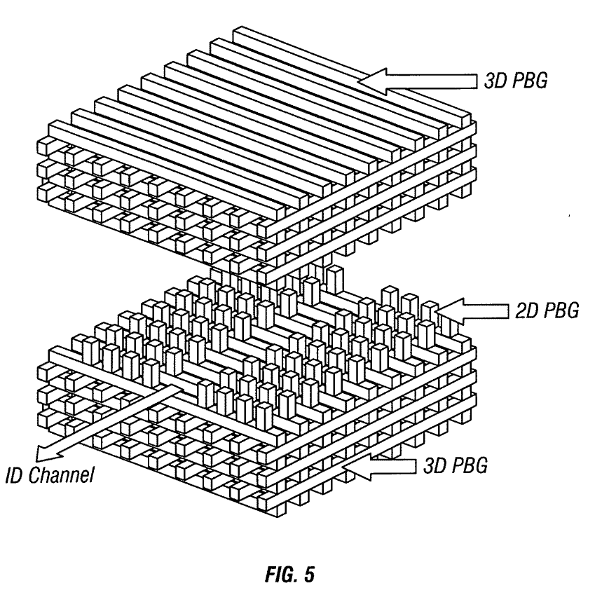

The angular control over the emission and absorption of the thermal radiation can be realized by introducing waveguide channels, i.e. linear defects in an otherwise unperturbed photonic crystal as shown in FIG. 3. FIG. 4 depicts the dispersion relation for the of waveguide architecture shown in FIG. 3, and displays the emergence of a guided mode in the band-gap region induced by the presence of the linear defect. Furthermore, additional confinement of radiation emission and absorption in the out of plane directions of propagation can be achieved by embedding the 2D structure in 2D-3D heterostructure as shown on the left panel of FIG. 5. Incidentally, we have also shown that simultaneous spectral and full angular control can be realized with a micro-structure consisting of a wave-guide channel in a 2D photonic crystal, sandwiched between suitable 3D PBG cladding layers. See M. Florescu, S. Scheel, H. Haeffner, H. Lee, D. V. Strekalov, P. L. Knight, J. P. Dowling, Europhysics Letters 69, 945 (2005). The 1D waveguide is generated by removing one row of rods in the Longitudinal direction. The 3D photonic crystal is a woodpile structure that presents a photonic band gap of about 20% of the mid-gap frequency. By tuning the characteristics of the microstructure (geometry and index of refraction contrast), the waveguide channel can support a single waveguide mode, i.e., over the spectral range of the photonic band gap there is only one direction available for emission and absorption of radiation. The structure shown in FIG. 5 presents an enhanced spectral response at a specific frequency that can be matched to the frequency of a photocell. On the right panel of FIG. 5, we show that the sharp cutoff of the guided mode at the Brillouin zone generates a strongly enhanced number of available electromagnetic modes, which determines in turn a dramatic increase in the rate of absorption and emission of radiation at that frequency and along the waveguide direction. Clearly, an absorber made out of this photonic crystal heterostructure provides both frequency-selective and angular-selective capabilities.

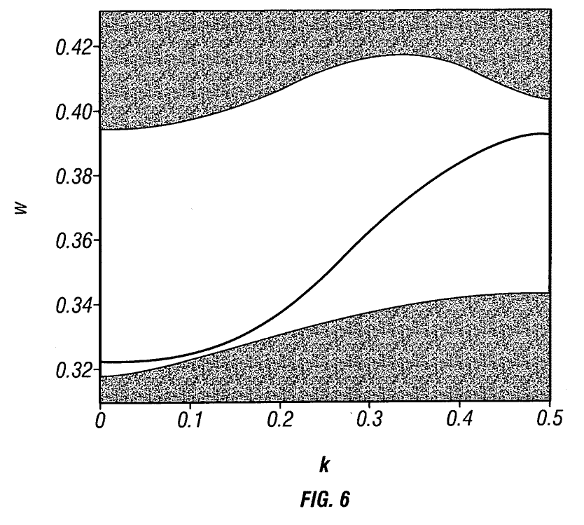

Another realization of wide-band angular selective photonic materials can be achieved by employing other waveguide architectures that allow for the total or partial confinement of the propagation of radiation in the out-of-plane directions. In particular, this can be done by employing omni-directional waveguides that use the concept of omni-directional mirrors—one dimensional periodic dielectric structures that reflect light from all incident angles and polarizations and extend it to systems with cylindrical symmetry, as depicted in the upper part of FIG. 6. See, e.g., P. Bermel, J. D. Joannopoulos, Y. Fink, A. Lane and C. Tapalian, Phys. Rev. B 69, 035316 (2004). Omnidirectional waveguides have been fabricated in fiber form, and show enhancement of the emission and absorption of radiation at well defined frequencies that can be matched to photocells band-gap frequency. See, e.g., S. Hart, G. Maskaly, B. Temelkuran, P. Prideaux, J. Joannopoulos, and Y. Fink, Science 296, 510 (2002); and B. Temelkuran, S. Hart, G. Benoit, J. Joannopoulos, and Y. Fink, Nature 420, 650 (2002). By stacking such omnidirectional absorbers in a square or triangular lattice is possible to achieve a large area angle and frequency selective absorber, as depicted on the lower part of FIG. 6.

Photonic-crystal based frequency and angle-selective device for high-efficiency solar energy converters

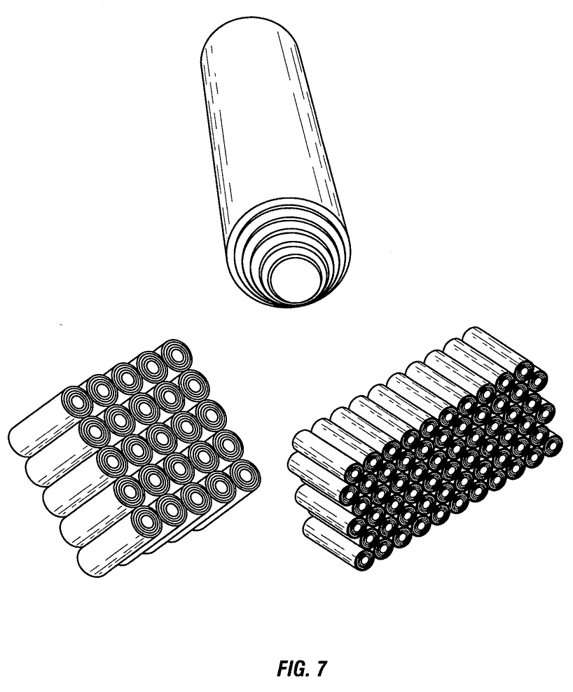

A photonic crystal-based solar energy conversion system presented in FIG. 7 consists of an angle-selective photonic crystal structure on the Sun-facing part of the device, an efficient radiation and heat absorbing conduit and a frequency selective photonic crystal based emitter of the photocell facing part. The design is completed with a photocell and a mirror. The Sun facing photonic crystal structure consist of wide band angular selective photonic-crystal based architectures such as the ones depicted in FIGS. 5 and 6 designed such that their angular enhanced optical response matches the directional characteristics of the solar thermal source. The radiation and heat absorber is in thermal contact with the angle-selective absorber and insures thermal equilibrium between it and a second photonic crystal based absorber/emitter system. This second photonic crystal based emitter, is designed to act as frequency-selective emitter, and also insures that the broad band radiation incident upon it is funneled into a narrow spectral range centered on the photocell band-gap frequency. As a result, the radiation incident upon the photocell is efficiently converted into a flux of charged particles. Finally, the residual radiation that escapes the photocell without being converted into electrons is directed back into the device, where it undergoes the same process.

This invention is susceptible to considerable variation in its practice. Therefore the foregoing description is not intended to limit, and should not be construed as limiting, the invention to the particular exemplifications presented hereinabove. Rather, what is intended to be covered is as set forth in the ensuing claims and the equivalents thereof permitted as a matter of law.

We claim:

1. A solar radiation absorber comprising at least one photonic crystal with absorptivity over a broad range of frequencies, improved absorptivity within a selected solid angle, and reduced absorptivity outside the selected solid angle.

2. The absorber of claim 1 wherein the broad range of frequencies is 0.1 to 2.4 microns.

3. The absorber of claim 1 wherein the broad range of frequencies is 0.32 to 2.4 microns.

4. The absorber of claim 1 wherein the selected solid angle is 1 degree.

5. The absorber of claim 1 wherein the selected solid angle is 0.5 degrees.

6. The absorber of claim 1 wherein the selected solid angle matches the angle subtended by the Sun.

7. The absorber of claim 1 wherein the at least one photonic crystal has at least two dielectric materials, the at least two dielectric materials chosen so as to create a photonic crystal with absorptivity over a broad range of frequencies, improved absorptivity within a selected solid angle, and reduced absorptivity outside the selected solid angle, and wherein at least one of the at least two dielectric materials has a complex dielectric constant.

8. The absorber of claim 7 wherein the absolute value of the real part is greater than or equal to the imaginary part of the complex dielectric constant of the at least one of the at least two dielectric materials.

9. The absorber of claim 7 wherein the absolute value of the real part of the complex dielectric constant of the at least one of the at least two dielectric materials is greater than or equal to 5.

10. The absorber of claim 7 wherein the at least one photonic crystal has a photonic band gap and exhibits a divergent density of states over the broad range of frequencies, and the divergent density of states occurs within an allowed band of the at least one photonic crystal.

11. The absorber of claim 7 wherein the at least one photonic crystal comprises a structure chosen from the group consisting of Lincoln-Log and inverted opal.

12. The absorber of claim 11 wherein the at least one photonic crystal further comprises a three-dimensional photonic crystal.

13. The absorber of claim 12 further comprising a two-dimensional photonic crystal.

14. The absorber of claim 13 further comprising a waveguide channel.

15. The absorber of claim 14 wherein the waveguide channel comprises replacing at least one of the at least two dielectric materials with another dielectric material in a region of the at least one photonic crystal.

16. The absorber of claim 7 wherein the photonic crystal has geometry and index refraction contrast, and wherein the geometry and/or index refraction contrast are chosen to support a single waveguide mode.

17. A radiation adaptor, comprising:
a) a solar radiation absorber including at least one photonic crystal with absorptivity over a broad range of frequencies, improved absorptivity within a selected solid angle, and reduced absorptivity outside the selected solid angle; and
b) a radiation emitter comprising at least one photonic crystal that can emit radiation within a broad range of emission angles, but only within a narrow range of frequencies;
c) wherein the absorber and emitter are in functional communication with one another.

18. A solar cell, comprising:
a) a solar radiation absorber including at least one photonic crystal with absorptivity over a broad range of frequencies, improved absorptivity within a selected solid angle, and reduced absorptivity outside the selected solid angle;
b) a radiation emitter comprising at least one photonic crystal that can emit radiation within a broad range of emission angles, but only within a narrow range of frequencies, in functional communication with the absorber;
c) a photovoltaic cell with a band-gap frequency, in functional communication with the absorber and the emitter; and
d) a mirror in functional communication with the absorber, the emitter, and the photovoltaic cell.

19. The solar cell of claim 18 wherein the narrow range of frequencies emitted by the radiation emitter is above the photovoltaic cell band-gap frequency.

20. The solar cell of claim 18 further comprising tracking means to track a radiation source.

21. A radiation absorber/emitter system comprising:
a) a periodically modulated angle- and frequency-selective absorber; and
b) a periodically modulated frequency-selective emitter;
wherein said system absorbs radiation from a broad range of frequencies, but only from a narrow range of incident angles matching the angle subtended by the Sun, and wherein said system funnels the absorber radiation into a narrow spectral range centered on the bandgap frequency of a photonic-to-electric energy conversion system.

22. The system of claim 21, wherein the absorber:
a) has a characteristic architecture;
b) has a characteristic lattice constant;
c) is made of dielectric and/or metallic materials
wherein the characteristic architecture, lattice constant, and materials are chosen to create an absorber that can absorb radiation from a broad range of frequencies centered on the solar spectral range, but only from a narrow range of incident angles centered on the angle subtended by the Sun.

23. The system of claim 22, wherein the characteristic lattice constant of the absorber is between 0.14 microns and 5 microns.

24. The system of claim 22, wherein the characteristic architecture presents a waveguided mode encompassing the spectral range of the photonic bandgap and oriented along the Sun's line of sight.

25. The system of claim 22, wherein said materials have characteristic dielectric permittivity and characteristic absorptivity, wherein said permittivity and absorptivity are chosen to create an absorber that can absorb radiation from a broad range of frequencies encompassing the spectral range of the photonic bandgap, but only from a narrow range of angles centered along the Sun's line of sight.

26. The system of claim 21, wherein the emitter:
a) has a characteristic architecture;
b) has a characteristic lattice constant;
c) is made of dielectric and/or metallic materials
wherein the characteristic architecture, lattice constant, and materials are chosen to create an emitter that can emit radiation into a narrow spectral range centered on the bandgap frequency of a photonic-to-electric energy conversion system.

27. The system of claim 26, wherein the characteristic lattice constant of the emitter is between 0.14 microns and 5 microns.

28. The system of claim 26, wherein the emitter emits into a spectral range between 0.14 and 3 microns.
